(19) United States
(12) Patent Application Publication
(10) Pub. No.: US 2019/0319575 A1
(43) Pub. Date: Oct. 17, 2019

(54) Systems and Methods for In-Situ Energy Storage and Control Within Solar Panel

(71) Applicant: The Charles Stark Draper Laboratory, Inc., Cambridge, MA (US)

(72) Inventor: Lisa McIlrath, Lexington, MA (US)

(21) Appl. No.: 16/379,962

(22) Filed: Apr. 10, 2019

Related U.S. Application Data
(60) Provisional application No. 62/656,942, filed on Apr. 12, 2018.

(51) Int. Cl. H02S 10/20; H02S 20/32; G05F 1/67; H01L 31/048

(52) U.S. Cl. CPC H02S 10/20; H01L 31/048; G05F 1/67; H02S 20/32

(57) ABSTRACT

An embedded energy storage system comprises an array of embedded storage solar cells and a panel combiner/converter configured to combine and coordinate the array of embedded storage solar cells. Each of the array of embedded storage solar cells may comprise a solar cell having a first surface that is light receptive and a second surface that is not light receptive, an array of micro super-capacitors (MSCs) disposed on a substrate, and one or more integrated circuit components disposed on the same or different substrate. If disposed on different substrates, the two substrates may be intimately connected using an advanced packaging technology. The substrate may be arranged to overlay the second surface of the solar cell, substantially adjacent to the second surface, with two or more electrical conductors configured to electrically couple the substrate to the solar cell.

### RELATED APPLICATION

This application claims the benefit of U.S. Provisional Application No. 62/656,942, filed on Apr. 12, 2018. The entire teachings of the above application are incorporated herein by reference.

### BACKGROUND

Energy storage is an essential part of any solution to overcome issues preventing solar and other renewable energy sources from displacing fossil fuels as the dominant source of electric power. Solutions must include providing constantly available power, eliminating regulatory curtailment that results in higher solar energy costs (see, e.g., Jovan Bebic, Chief Engineer Electric Power, GE Global Research, “Lowering Wholesale Energy Prices by Transmission Control and Energy Storage,” MIT Energy Workshop, September 2017), and increasing reliability by providing the ride-through capability for inverter-connected generators to properly respond to disturbances on the grid (see, e.g., Kroposki, B.; Johnson, B; Zhang, Y.; Gevorgian, V.; Denholm, P.; Hodge, B-M.; and Hannegan, B.; “Achieving a 100% Renewable Grid: Operating Electric Power Systems with Extremely High Levels of Variable Renewable Energy,” IEEE Power and Energy Magazine, March 2017).

Due to the central role of energy storage in developing a clean grid, research into improving energy storage systems has been intense. Still, most solutions remain cost-prohibitive, require large areas for their installation, a need for climate-controlled conditions, and substantial resistive wiring losses in transferring the energy from the solar panels to the energy storage devices. Some battery technologies, such as Lithium-ion, exhibit long charging times and are limited in the maximum number of cycles allowed before their performance degrades. FIG. 1, which depicts current trends in the cost of storage capacity in $/kWh, indicates that it will be more than a decade for Li-ion battery storage to become cost-competitive for grid applications (see, e.g., Hart, D. and Sarkissian, A.; “Deployment of Grid-Scale Batteries in the United States,” prepared for the Office of Energy Policy and Systems Analysis, U.S. Department of Energy, June 2016).

### SUMMARY

The described embodiments are directed to solar storage elements of a solar panel system, with each of the solar storage elements comprising an embedded energy storage system.

In one aspect, the invention may be an embedded energy storage element, comprising a solar cell having a first surface that is light receptive and a second surface on a side of the solar cell opposite to that of the first surface. The embedded energy storage element may further comprise an array of micro super-capacitors (MSCs) disposed on a substrate, and one or more integrated circuit components disposed on the substrate. The substrate may be arranged to overlay the second surface of the solar cell, substantially adjacent to the second surface, with one or more electrical conductors configured to electrically couple the substrate to the solar cell.

The embedded energy storage element may further comprise an enclosure configured to encapsulate the solar cell and the substrate. The enclosure is configured to hermetically seal the solar cell and the substrate.

The one or more integrated circuit components may comprise control circuits configured to control the MSCs. The one or more integrated circuit components may comprise processing circuits configured to perform maximum power point tracking associated with the solar cell. The one or more integrated circuit components may comprise interface circuits configured to perform and control communications activities either between the solar cell and the substrate, between the embedded energy storage system and an external entity, or both. The substrate is a thin film.

The embedded energy storage element may be electrically and physically associated with one or more additional embedded energy storage elements to form a storage module. The embedded energy storage elements of the storage module may be electrically coupled to an energy storage control and maximum power point tracking (ES control and MPPT) component configured to control the embedded energy storage elements of the storage module, and to perform maximum power point tracking of the embedded energy storage elements of the storage module.

The ES control and MPPT component may be distributed across the substrates of the embedded storage elements. The storage module may be electrically and physically associated with one or more additional storage modules to form a solar panel. The solar panel may be electrically coupled to a panel combiner/converter configured to combine the outputs of the storage modules of the solar panel, transmit signals to the ES control and MPPT components to regulate power flow, and perform DC to DC conversion to interface to a system inverter. The panel combiner/converter may be distributed across the substrates of the embedded storage elements.

In another aspect, the invention may be an embedded energy storage system, comprising an array of embedded storage solar cells. Each of the embedded storage solar cells may comprise (i) a solar cell having a first surface that is light receptive and a second surface on a side of the solar cell opposite to that of the first surface, (ii) an array of micro super-capacitors (MSCs) disposed on a substrate, and one or more integrated circuit components disposed on the substrate. The substrate may be arranged to overlay the second surface of the solar cell, substantially adjacent to the second surface, with one or more electrical conductors configured to electrically couple the substrate to the solar cell. The embedded energy storage system may further comprise a panel combiner and converter configured to combine the array of embedded storage solar cells and coordinate operation of the embedded storage solar cells.

The embedded energy storage system may further comprise an enclosure configured to hermetically encapsulate each of the embedded storage solar cells. The embedded energy storage system may further comprise an enclosure configured to hermetically encapsulate the array of embedder storage solar cells.

The one or more integrated circuit components may comprise one or more control circuits configured to control the MSCs. The one or more integrated circuit components may comprise processing circuits configured to perform maximum power point tracking associated with the solar cell.

The one or more integrated circuit components may comprise interface circuits configured to perform and control communications activities either between the solar cell and the substrate, between the embedded energy storage system and an external entity, or both. The substrate may be a thin film.

One or more subsets of the embedded storage solar cells may be electrically coupled to an energy storage control and maximum power point tracking (ES control and MPPT) component configured to control the embedded energy storage elements of the storage module and perform maximum power point tracking of the embedded energy storage elements of the storage module.

The one or more subsets of the embedded storage solar cells electrically may be electrically coupled to a panel combiner/converter configured to combine the outputs of the storage modules of the solar panel, transmit signals to the ES control and MPPT components to regulate power flow, and perform DC to DC conversion to interface to a system inverter.

### BRIEF DESCRIPTION OF THE DRAWINGS

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1 shows current trends in the cost of storage capacity.

FIGS. 2A, 2B and 2C show components of the architecture of the described embodiments according to the invention.

FIG. 3 shows an example embodiment of an MSC constructed and arranged according to the invention.

FIG. 4 shows an example of an MSC according to the invention fabricated as a thin film deposition.

FIG. 5 shows the Ragone plot of different traditional battery technologies.

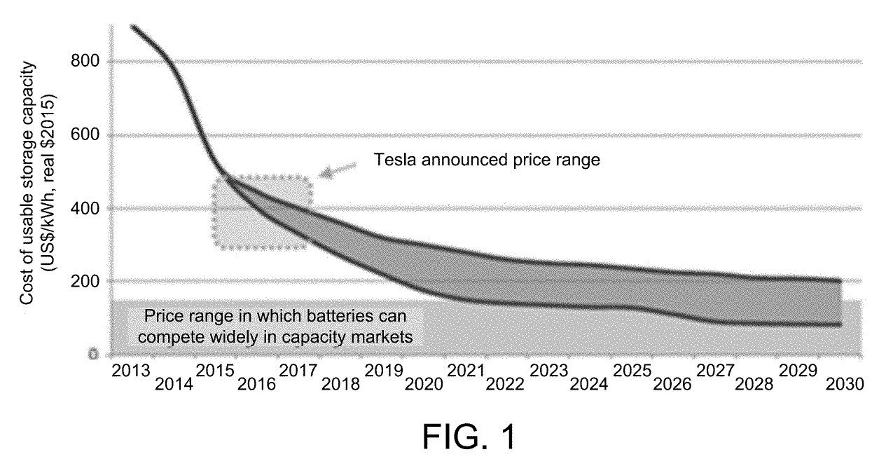

### DETAILED DESCRIPTION

A description of example embodiments follows.

The teachings of all patents, published applications and references cited herein are incorporated by reference in their entirety.

The described embodiments are directed to carbon-enhanced micro super-capacitors (MSCs) as an energy storage system architecture configured to provide low-volume, high capacity storage directly coupled to solar cells. The MECs of the described embodiments can be deposited directly on silicon, or on thin-film flexible substrates, and can provide power and energy densities orders of magnitude greater than rechargeable batteries. The described embodiments comprise a solar panel implementation with MSCs fully integrated within the individual solar cells. Further, the described solar panel architecture may include analog and/or digital integrated circuits for controlling the storage of energy and the release of stored energy, as well as providing maximum power point tracking (MPPT) for in-situ power optimization. The analog and/or integrated circuits may be disposed on the same substrate that hosts the MSCs, or on one or more separate, distinct substrates. If the analog and/or digital integrated circuits are disposed on one or more distinct substrates, the MSC substrate(s) and the circuit substrate(s) may be coupled physically and/or electrically, using an appropriate packaging technology.

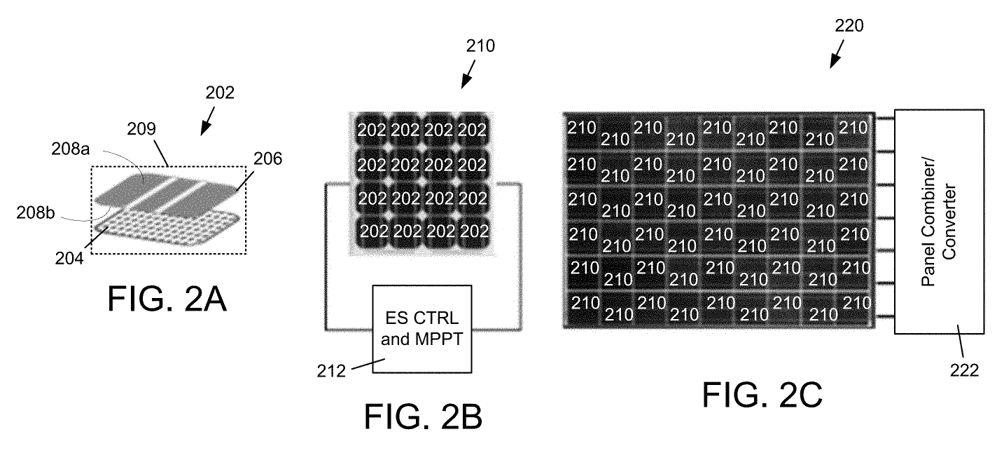

FIGS. 2A, 2B and 2C show architectural components of an example embodiment, which illustrate innovative features of the described embodiments. Storage elements 202, containing arrays of MSCs on a light-weight substrate 204, of roughly the same dimensions as the solar cell 206, are designed to provide 50-100 J/V²-cm² of storage (e.g., 12-24 KJ/V² for a six-inch by six-inch square cell). The solar cell 206 is characterized by a first surface 208a that is receptive to light, and a second surface 208b on a side opposite to that of the first surface 201a (i.e., the flip side of the solar cell 206). The first surface 208a and the second surface 208b are substantially parallel. Electrical components (e.g., CMOS components, although other electrical component family types may also be used) may be integrated with the same substrate 204 that hosts the MSCs. Inexpensive integration technologies (e.g., 0.25 μm to 0.35 μm) may be implemented to reduce overall cost while providing satisfactory performance, although in alternative embodiments other technologies may be used. The substrate 204 may be disposed adjacent to the second surface 208b of the solar cell 206, as shown in FIG. 2A (in which the substrate 204 and the solar cell 206 are shown slightly separated), and the substrate/solar cell pair of a storage element 202 may be encased in a sealed enclosure 209 (e.g., the substrate/solar cell pair may be coupled together in a hermetically sealed package). Although the sealed enclosure 209 is shown conceptually in FIG. 2A as a dotted-lined box, the sealed enclosure may be implemented as a fitted casing that follows the contours of the substrate/solar cell assembly. The solar cell 206 may be electrically coupled to the substrate 204 and to the components thereon.

Several (e.g., 10-20) of the storage elements 202 may be ganged into storage modules 210 to yield a total voltage drop of roughly 5-10V over a series chain of solar cells. FIG. 2B illustrates a storage module 210 comprising 16 storage elements 202. At this voltage, low-cost, fast-switching CMOS technologies (in contrast to power electronics with discrete semiconductor devices) can be used to design an integrated circuit controller that can both direct the flow of current to and from the storage elements and provide in-situ maximum power point tracking (MPPT). The energy storage (ES) control and MPPT component 212 is shown conceptually in the example embodiment depicted in FIG. 2B. The electrical components that perform the ES control and MPPT functionality may be disposed directly on the MSC substrate 202 and distributed across the constituent storage elements 202, as described above. Because the ES control and MPPT component 212 is embedded in the storage module 210, the MPPT functionality may be performed locally in small groups of solar cells. Consequently, the energy yield of the overall solar panel 220 may be enhanced, particularly in shaded or faulted conditions.

The weight and volume of the ES control and MPPT component 212 is very small relative to the solar cells 206 themselves, so the combined storage elements and ES control and MPPT components 212 can be packaged hermetically to withstand the harsh environmental conditions within the solar panel 220, thereby extending their lifetime to years of operation. Finally, a panel-level controller/converter component 222 combines the outputs of the storage modules 210, transmits signals to the ES control and MPPT components 212 to regulate power flow, and performs direct-current to direct-current (DC to DC) conversion to interface to the system inverter. While the controller/converter component 222 may be implemented as a stand-alone device, in some embodiments the controller/converter component 222 may be distributed across the substrates 204 as are the ES control and MPPT components 212.

An innovation of the described embodiments is the micro super-capacitor technology incorporated in the solar panel along with low-voltage, low-power CMOS control circuits. The described embodiments may remove many of the major barriers to increased solar energy penetration. The fabrication costs for the combined storage elements and control circuits may be low and will thus not significantly impact the total cost of solar installations, residential or utility. Given that the storage-enhanced panels will be more efficient and will provide energy for longer periods of the day, the actual cost per Watt-hour may in fact decrease.

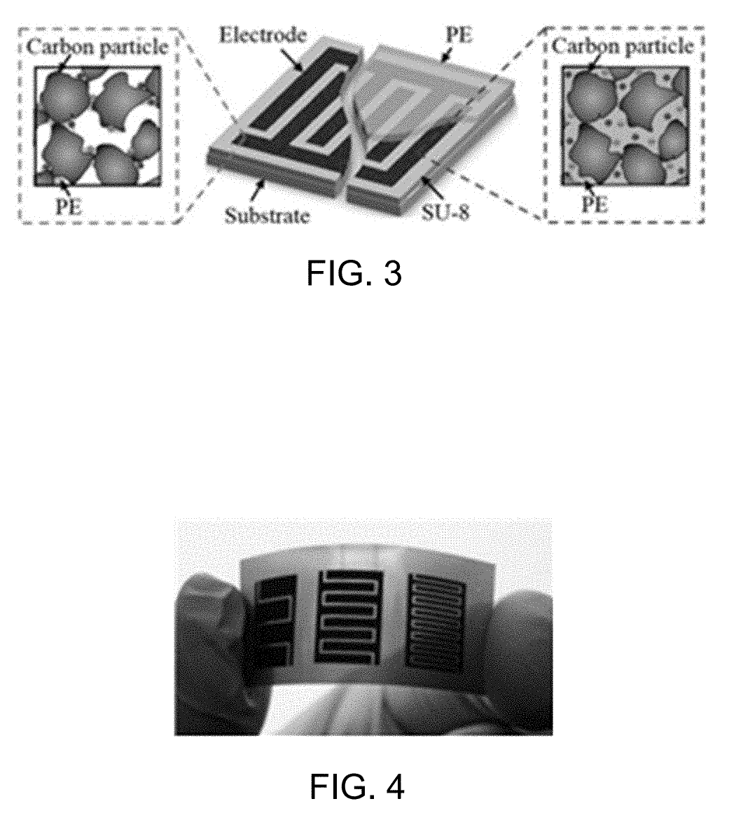

Unlike traditional super-capacitors, which have existed for decades and can be purchased as (relatively pricey) discrete components, the MSC technology of the described embodiments is an active area of research in which performances, especially energy and power densities, have been improving rapidly in recent years (see, e.g., Shen, C.; Xu, S.; Xie, Y.; Sanghadasa, M.; Wang, X.; and Lin, L; “A Review of On-Chip Micro Supercapacitors for Integrated Self-Powering Systems,” J. Microelectromechanical Systems, Vol. 26, No. 5, October 2017). FIG. 3 shows an example embodiment of an MSC constructed and arranged according to the invention. FIG. 4 shows an example of an MSC according to the invention fabricated as a thin film deposition.

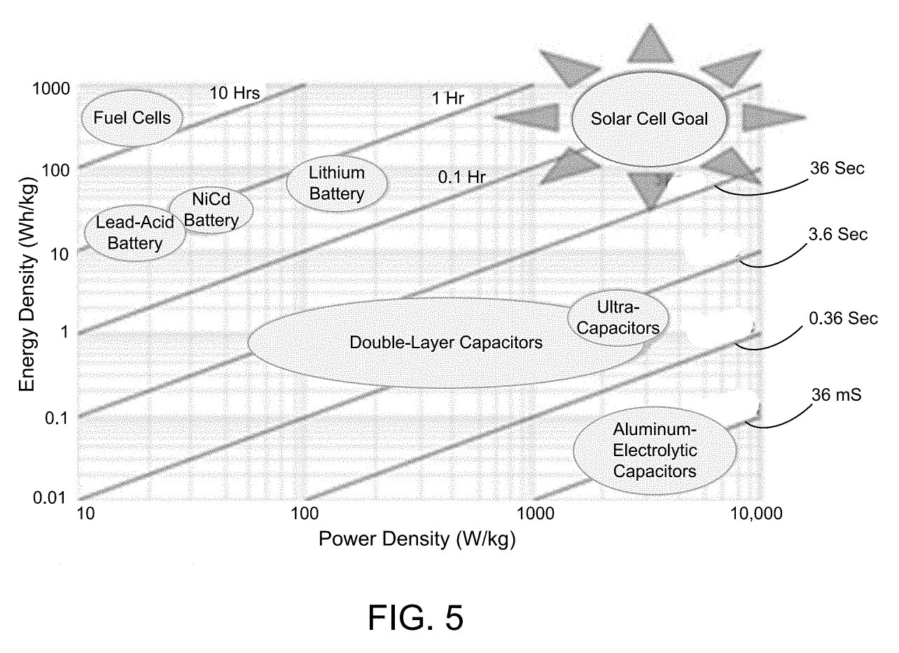

The weight of the MSCs is very low, relative to the solar cells, and can achieve capacitances as high as 1000 F/cm³. Their energy density, which is a function of the voltage squared, can be tailored to specific applications. Power densities can also be regulated by varying the duty cycle of current-switching transistors in the converter/controller component 222. FIG. 5 shows the (gravimetric) Ragone plot of different traditional battery technologies. The sloping lines in FIG. 5 describe the amount of time necessary to charge or discharge the battery. (see, e.g., “Battery Performance Characteristics,” http://www.mpoweruk.com/performance.htm) along with the region where solar cells are ideally situated. The described embodiments will facilitate reaching that goal at lower cost and overhead than any current battery technology.

Fabrication processes for producing the storage elements of the described embodiments may include, but are not limited to, carbon nanotubes, graphene hydrogel with activated carbon in a binder, and laser-scribed dry graphene. Each of these fabrication processes exhibit particular properties and characteristics, and a specific process may be selected based on numerous criteria, including storage density, ease of fabrication, and reliability. In an example embodiment, carbon nanotubes may be deposited directly on a silicon wafer substrate through chemical vapor deposition (CVD). Simple masking may be implemented to define a catalyst, then deposition.

The ES control and MPPT components 212 may be fabricated through available CMOS foundries and tested with the storage samples. In some embodiments, the energy storage system architecture described herein may be supplemented with external storage devices. For example, during peak energy production, excess generated energy may be directed to external storage devices.

While example embodiments have been particularly shown and described, it will be understood by those skilled in the art that various changes in form and details may be made therein without departing from the scope of the embodiments encompassed by the appended claims.

What is claimed is:

1. An embedded energy storage element, comprising:
a solar cell having a first surface that is light receptive and a second surface on a side of the solar cell opposite to that of the first surface;
an array of micro super-capacitors (MSCs) disposed on a substrate;
one or more integrated circuit components disposed on the substrate;
the substrate arranged to overlay the second surface of the solar cell, substantially adjacent to the second surface, with one or more electrical conductors configured to electrically couple the substrate to the solar cell.

2. The embedded energy storage element of claim 1, further comprising an enclosure configured to encapsulate the solar cell and the substrate.

3. The embedded energy storage element of claim 2, wherein the enclosure is configured to hermetically seal the solar cell and the substrate.

4. The embedded energy storage element of claim 1, wherein the one or more integrated circuit components comprises control circuits configured to control the MSCs.

5. The embedded energy storage element of claim 1, wherein the one or more integrated circuit components comprises processing circuits configured to perform maximum power point tracking associated with the solar cell.

6. The embedded energy storage element of claim 1, wherein the one or more integrated circuit components comprises interface circuits configured to perform and control communications activities either between the solar cell and the substrate, between the embedded energy storage system and an external entity, or both.

7. The embedded energy storage element of claim 1, wherein the substrate is a thin film.

8. The embedded energy storage element of claim 1, wherein the embedded energy storage element is electrically and physically associated with one or more additional embedded energy storage elements to form a storage module, the embedded energy storage elements of the storage module being electrically coupled to an energy storage control and maximum power point tracking (ES control and MPPT) component configured to control the embedded energy storage elements of the storage module and perform maximum power point tracking of the embedded energy storage elements of the storage module.

9. The embedded energy storage element of claim 8, wherein the ES control and MPPT component is distributed across the substrates of the embedded storage elements.

10. The embedded energy storage element of claim 8, wherein the storage module is electrically and physically associated with one or more additional storage modules to form a solar panel, the solar panel being electrically coupled to a panel combiner/converter configured to combine the outputs of the storage modules of the solar panel, transmit signals to the ES control and MPPT components to regulate power flow, and perform DC to DC conversion to interface to a system inverter.

11. The embedded energy storage element of claim 10, wherein the panel combiner/converter is distributed across the substrates of the embedded storage elements.

12. An embedded energy storage system, comprising:
an array of embedded storage solar cells, each of which comprises:
a solar cell having a first surface that is light receptive and a second surface on a side of the solar cell opposite to that of the first surface;
an array of micro super-capacitors (MSCs) disposed on a substrate; and
one or more integrated circuit components disposed on the substrate;
the substrate arranged to overlay the second surface of the solar cell, substantially adjacent to the second surface, with one or more electrical conductors configured to electrically couple the substrate to the solar cell; and
a panel combiner and converter configured to combine the array of embedded storage solar cells and coordinate operation of the array of embedded storage solar cells.

13. The embedded energy storage system of claim 12, further comprising an enclosure configured to hermetically encapsulate each of the embedded storage solar cells.

14. The embedded energy storage system of claim 12, further comprising an enclosure configured to hermetically encapsulate the array of embedder storage solar cells.

15. The embedded energy storage system of claim 12, wherein the one or more integrated circuit components comprises one or more control circuits configured to control the MSCs.

16. The embedded energy storage system of claim 12, wherein the one or more integrated circuit components comprises one or more processing circuits configured to perform maximum power point tracking associated with the solar cell.

17. The embedded energy storage system of claim 12, wherein the one or more integrated circuit components comprises interface circuits configured to perform and control communications activities either between the solar cell and the substrate, between the embedded energy storage system and an external entity, or both.

18. The embedded energy storage system of claim 12, wherein the substrate is a thin film.

19. The embedded energy storage system of claim 12, wherein one or more subsets of the embedded storage solar cells are electrically coupled to an energy storage control and maximum power point tracking (ES control and MPPT) component configured to control the embedded energy storage elements of the storage module and perform maximum power point tracking of the embedded energy storage elements of the storage module.

20. The embedded energy storage system of claim 19, wherein the one or more subsets of the embedded storage solar cells are electrically coupled to a panel combiner/converter configured to combine the outputs of the storage modules of the solar panel, transmit signals to the ES control and MDPT components to regulate power flow, and perform DC to DC conversion to interface to a system inverter.
